(19) United States
(12) Patent Application Publication
(10) Pub. No.: US 2023/0207736 A1
(43) Pub. Date: Jun. 29, 2023

(54) LIGHT EMITTING DIODE WITH VERTICAL STRUCTURE AND MANUFACTURING METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/175,288

(22) Filed: Feb. 27, 2023

Related U.S. Application Data
(63) Continuation of application No. PCT/CN2020/128095, filed on Nov. 11, 2020.

(51) Int. Cl. H01L 33/38; H01L 33/12; H01L 33/32; H01L 33/00

(52) U.S. Cl. CPC H01L 33/382; H01L 33/12; H01L 33/32; H01L 33/0075; H01L 2933/0016

(57) ABSTRACT

Disclosed are a light emitting diode with a vertical structure and a manufacturing method thereof. The manufacturing method includes: forming a metal atom layer on a substrate, the substrate being an n-type substrate; forming an n-type buffer layer on the metal atom layer; forming a light emitting structure on the n-type buffer layer, the light emitting structure including an n-type semiconductor layer, an active layer and a p-type semiconductor layer from bottom to top; disposing a p electrode on the light emitting structure; and disposing an n electrode on one side, away from the metal atom layer, of the substrate. The n-type substrate with conductivity is adopted, and the metal atom layer and the n-type buffer layer are sequentially formed on the n-type substrate, so that conductivity of a device with the vertical structure can be ensured, and stripping and bonding are not needed.

### CROSS-REFERENCE TO RELATED APPLICATIONS

The present application is a continuation application of International Application No. PCT/CN2020/128095, filed on Nov. 11, 2020, which is incorporated herein by reference in its entirety.

### TECHNICAL FIELD

The present application relates to the field of light emitting diode technologies, and in particular, to a light emitting diode with a vertical structure and a manufacturing method thereof.

### BACKGROUND

Compared with a traditional Light Emitting Diode (LED) with a planar structure, a light emitting diode with a vertical structure has great advantages in light output efficiency, a heat dissipation speed and so on.

### SUMMARY

The present application provides a manufacturing method without stripping and bonding and used to manufacture a light emitting diode with a vertical structure. The manufacturing method includes forming a metal atom layer on a substrate, the substrate being an n-type substrate; forming an n-type buffer layer on the metal atom layer; forming a light emitting structure on the n-type buffer layer, the light emitting structure including an n-type semiconductor layer, an active layer and a p-type semiconductor layer from bottom to top; disposing a p electrode on the light emitting structure; and disposing an n electrode on one side, away from the metal atom layer, of the substrate.

In an embodiment, the metal atom layer is an Al atom layer.

In an embodiment, the forming a metal atom layer on a substrate includes: forming the metal atom layer with a patterned structure on the substrate, and the patterned structure includes a continuous pattern and a discontinuous pattern.

In an embodiment, the forming the metal atom layer with a patterned structure on the substrate includes: patterning an upper surface of the substrate; and forming the metal atom layer on the upper surface of the substrate with the patterned structure, so that the metal atom layer has the patterned structure.

In an embodiment, the forming a metal atom layer on a substrate includes: partially forming the metal atom layer on the substrate.

In an embodiment, the partially forming the metal atom layer on the substrate includes: patterning an upper surface of the substrate; and forming the metal atom layer on a partial region of the upper surface of the substrate with a patterned structure.

In an embodiment, before disposing an n electrode on one side, away from the metal atom layer, of the substrate, the manufacturing method further includes: performing a thinning processing on the one side, away from the metal atom layer, of the substrate.

In an embodiment, the thinning processing includes at least one of etching and polishing.

In an embodiment, at least one groove is disposed on the substrate for separating the substrate into multiple pre-discrete structures; and a thickness of a thinned substrate is less than or equal to a depth of the at least one groove based on the thinning processing, so as to separate the multiple pre-discrete structures into multiple light emitting units that are independent from each other.

In an embodiment, the at least one groove is filled with an insulating material.

In an embodiment, the disposing an n electrode on one side, away from the metal atom layer, of the substrate includes: disposing the n electrode on the one side, away from the metal atom layer, of each of the multiple light emitting units.

The present application also provides a light emitting diode with a vertical structure manufactured by the above manufacturing method. The light emitting diode with the vertical structure includes: a substrate, the substrate being an n-type substrate; a metal atom layer formed on the substrate; an n-type buffer layer formed on the metal atom layer; a light emitting structure formed on the n-type buffer layer, the light emitting structure including an n-type semiconductor layer, an active layer and a p-type semiconductor layer from bottom to top; a p electrode disposed on the light emitting structure; and an n electrode disposed on one side, away from the metal atom layer, of the substrate.

In an embodiment, the metal atom layer is an Al atom layer.

In an embodiment, the metal atom layer has a patterned structure, and the patterned structure includes a continuous pattern and a discontinuous pattern.

In an embodiment, an upper surface of the substrate has the patterned structure corresponding to the metal atom layer.

In an embodiment, materials of the n-type semiconductor layer and the p-type semiconductor layer are group III-Nitrides.

In an embodiment, a horizontal width of the light emitting diode with the vertical structure is less than 500 μm.

In an embodiment, a horizontal width of the light emitting diode with the vertical structure is less than 100 μm.

Further, the present application also provides an LED display panel, including the light emitting diode with the vertical structure provided by any of the above embodiments.

### BRIEF DESCRIPTION OF THE DRAWINGS

FIG. 1 is a schematic flowchart of a manufacturing method for a light emitting diode with a vertical structure according to an embodiment of the present application.

FIG. 2 is a schematic flowchart of a manufacturing method for a light emitting diode with a vertical structure according to another embodiment of the present application.

FIG. 3A to FIG. 3F are schematic structural diagrams illustrating a manufacturing method for a light emitting diode with a vertical structure according to an exemplary of the present application.

FIG. 4 is a schematic structural diagram of a light emitting diode with a vertical structure according to an embodiment of the present application.

FIG. 5 is a schematic structural diagram of a light emitting diode with a vertical structure according to another embodiment of the present application.

FIG. 6 is a schematic structural diagram of a light emitting diode with a vertical structure according to another embodiment of the present application.

FIG. 7 is a schematic structural diagram of a light emitting diode with a vertical structure according to another embodiment of the present application.

FIG. 8 is a schematic structural diagram of a light emitting diode with a vertical structure according to another embodiment of the present application.

FIG. 9 is a schematic structural diagram of a light emitting diode with a vertical structure according to another embodiment of the present application.

### DETAILED DESCRIPTIONS OF THE EMBODIMENTS

The technical solutions of the present application may be clearly and completely described with reference to the accompanying drawings in the embodiments of the present application. Obviously, the described embodiments are a part of the embodiments of the present application rather than all the embodiments. Based on the embodiments of the present application, all other embodiments obtained by those of ordinary skill in the art without creative work fall within the protection scope of this application.

The manufacturing method for a light emitting diode with a vertical structure is significantly complicated. After the light emitting structure is formed, it is usually necessary to strip a substrate used to grow an epitaxial layer and bond the epitaxial layer to a new substrate with high conductivity. Due to this complex manufacturing process, it is difficult to improve production efficiency of the light emitting diode with the vertical structure. In addition, there are still various problems in a stripping process, which seriously affect a manufacturing cost and yield of the light emitting diode. For example, a laser stripping process (mainly for a sapphire substrate) is costly, and when a chemical etching stripping process (mainly for a silicon substrate) is adopted, poor efficiency and yield are poor, and the stripped substrate cannot be reused.

The main reasons for adopting the above complex manufacturing method are that the substrate does not have good conductivity, and if the stripping process is not performed, a power of a device may be seriously affected.

In order to overcome the above technical problems, people always research how to improve the stripping process, so as to improve stripping efficiency, reduce the cost and impact on the device, and the like. However, these methods are all limited to the stripping process, and production efficiency of the light emitting diode with the vertical structure cannot be fundamentally improved.

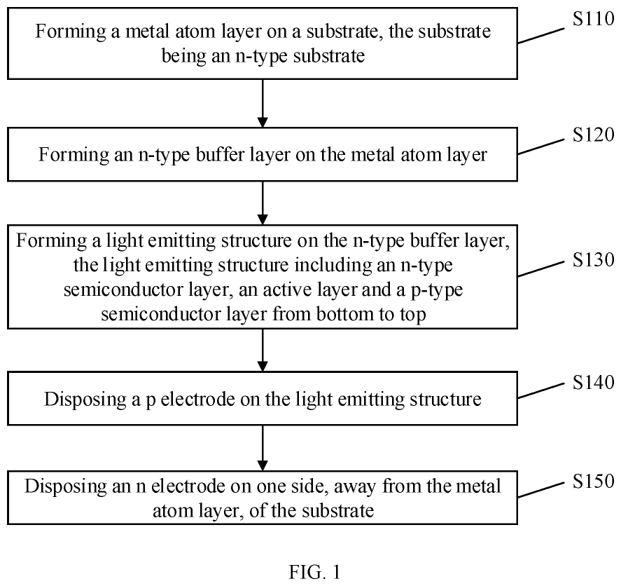

FIG. 1 is a schematic flowchart of a manufacturing method for a light emitting diode with a vertical structure according to an embodiment of the present application. As shown in FIG. 1, the manufacturing method including the following contents.

S110: forming a metal atom layer on a substrate, the substrate being an n-type substrate.

Since the n-type substrate has good conductivity and thermal conductivity, in the embodiment of the present application, the n-type substrate is used, an epitaxial layer may be gown directly on the substrate, and an n electrode is directly disposed on a back of the substrate, so that the substrate does not need to be stripped, thereby simplifying the manufacturing method, and saving the manufacturing cost.

Since the metal is opaque, the light emitted by the light emitting structure can be reflected under an action of the metal atom layer under the light emitting structure, so that light extraction efficiency of the light emitting diode with the vertical structure is effectively increased. At the same time, since the substrate has strong light absorption, and the metal atom layer is disposed above the substrate, so that adverse influence of the substrate on a luminous effect of the light emitting diode with the vertical structure may be effectively prevented.

Specifically, as shown in FIG. 4, in an embodiment, the metal atom layer 450 may be a tiled layer.

In another embodiment, the metal atom layer has a patterned structure. The light emitted by the light emitting structure can be reflected in more directions under the action of the metal atom layer with the patterned structure, which can further improve the light extraction efficiency of the light emitting diode with the vertical structure.

Specifically, the patterned structure of the metal atom layer may be realized in many ways.

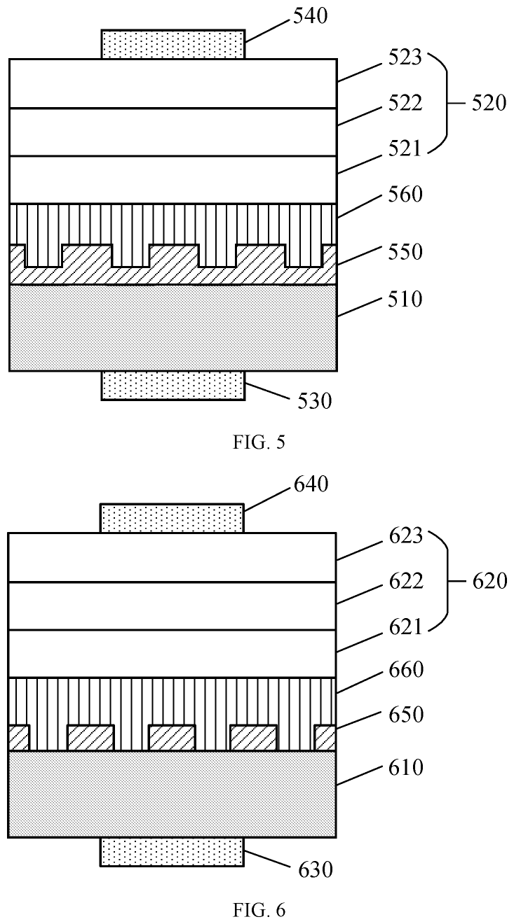

For example, as shown in FIG. 5, after a metal atom layer 550 is formed, a surface of the metal atom layer 550 is patterned to obtain the metal atom layer 550 with a continuous patterned structure.

For yet example, as shown in FIG. 6, a metal atom layer 650 is patterned to obtain the metal atom layer 650 with a discontinuous patterned structure.

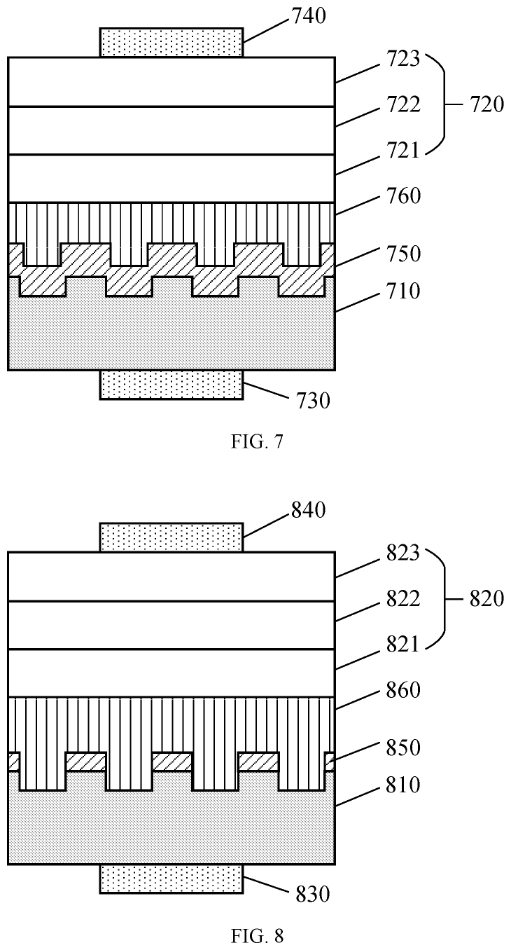

For still example, as shown in FIG. 7, before a metal atom layer 750 is formed, an upper surface of a substrate 710 is patterned first, and then a uniform metal atom layer 750 is formed on the upper surface of the substrate 710 with the patterned structure. In this way, the metal atom layer 750 may have the patterned structure corresponding to the patterned structure of the substrate 710.

For still example, as shown in FIG. 8, before a metal atom layer 850 is formed, an upper surface of a substrate 810 is patterned first, and the metal atom layer 850 is formed only between concave regions on the patterned structure of the substrate 810, so as to obtain a discontinuous metal atom layer 850 corresponding to the patterned structure of the substrate 810.

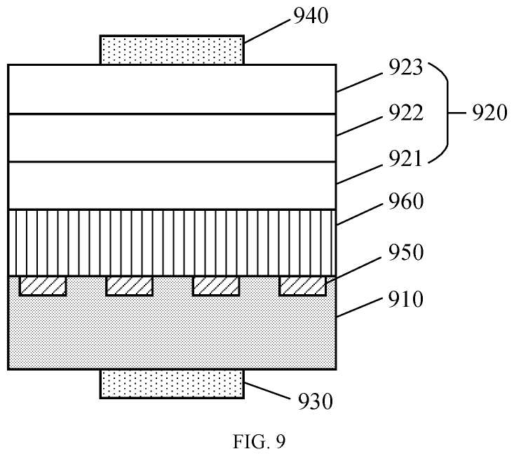

For still example, as shown in FIG. 9, before a metal atom layer 950 is formed, an upper surface of the substrate 910 is patterned first, and the metal atom layer 950 is formed only in concave regions on the patterned structure of the substrate 910, so as to obtain a discontinuous metal atom layer 950 corresponding to the patterned structure of the substrate 910.

Patterning the substrate is less difficult and more effective than directly patterning the metal atom layer. Therefore, according to the method of the embodiment, it is easier to pattern the metal atom layer while improving a product quality of a device.

It should be understood that a method for making the metal atom layer have the patterned structure does not limit in the embodiments of the present application, and those of skill in the art may choose according to their actual needs.

Further, in an embodiment, the metal atom layer may be an Al atom layer. Since an Al element and a Ga element are homologous elements, in the case of manufacturing the group III- Nitride buffer layer on the Al atom layer, the buffer layer can be better grown, and a quality of the buffer layer can be improved.

S120: forming an n-type buffer layer on the metal atom layer.

Specifically, a material of the n-type buffer layer may choose the group III-Nitride, such as gallium nitride or aluminum gallium nitrogen.

Here, a stress, caused by the growth of the epitaxial layer on the substrate, may be greatly alleviated based on the buffer layer, and dislocation filtering is realized, so that a crystal quality of the epitaxial layer can be improved.

S130: forming a light emitting structure on the n-type buffer layer, the light emitting structure including an n-type semiconductor layer, an active layer and a p-type semiconductor layer from bottom to top.

The n-type semiconductor layer may be composed of the group III-Nitrides, such as gallium nitride or aluminum gallium nitride. The p-type semiconductor layer may be composed of the group III-Nitrides, such as gallium nitride or aluminum gallium nitride. Electrons from the n-type semiconductor layer and electron holes from the p-type semiconductor layer are combined in the active layer to release energy, so that light emission is realized.

In an embodiment, the active layer may be a Multi-quantum Well (MQW) layer.

S140: disposing a p electrode on the light emitting structure.

S150: disposing an n electrode on one side, away from the metal atom layer, of the substrate.

Based on the manufacturing method for the light emitting diode with the vertical structure provided in the embodiments of the present application, the n-type substrate with conductivity is adopted, and the metal atom layer and the n-type buffer layer are sequentially formed on the n-type substrate, so that conductivity of a device with the vertical structure can be ensured, and stripping and bonding are not needed after the layer structure is formed, thereby reducing manufacturing steps, effectively saving a manufacturing cost of the light emitting diode with the vertical structure, and improving manufacturing efficiency. In addition, the metal atom layer is disposed, and the metal atom layer may also have the patterned structure, so that a process flow of the light emitting diode with the vertical structure is simplified while effectively improving light extraction efficiency of the light emitting diode with the vertical structure.

Optionally, in another embodiment, before the step S150, the manufacturing method shown in FIG. 1 may also include: performing a thinning processing on the one side, away from the metal atom layer, of the substrate.

The thinning processing may include one or more combinations of etching, polishing, and other methods. The thinning processing is performed on the substrate, so that a resistance of the substrate may be further reduced, and conductivity of a whole layer structure may be improved, improving luminous efficiency of the light emitting diode with the vertical structure.

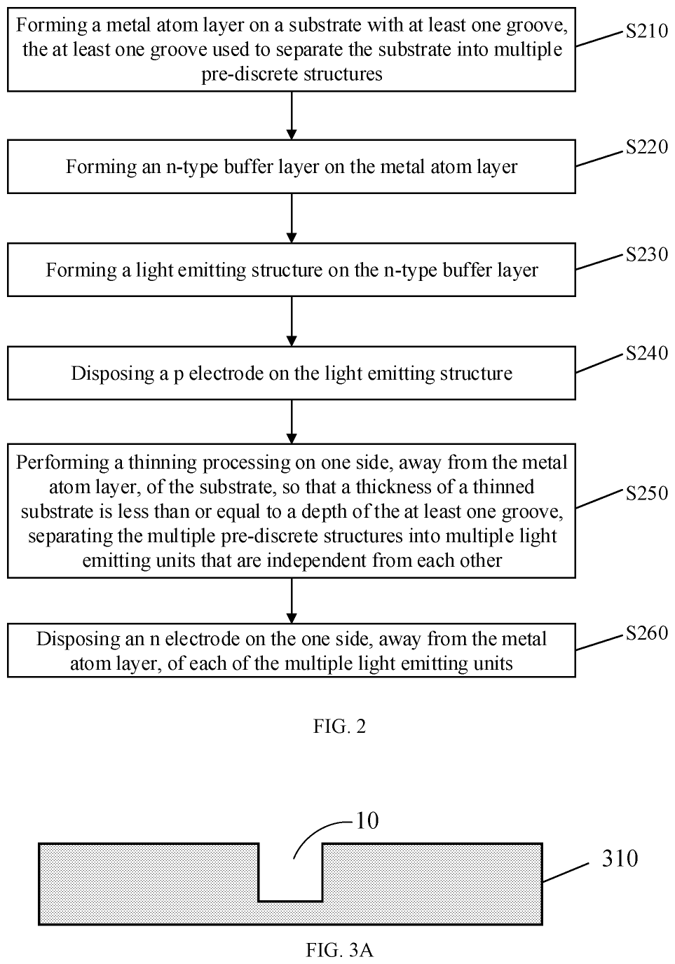

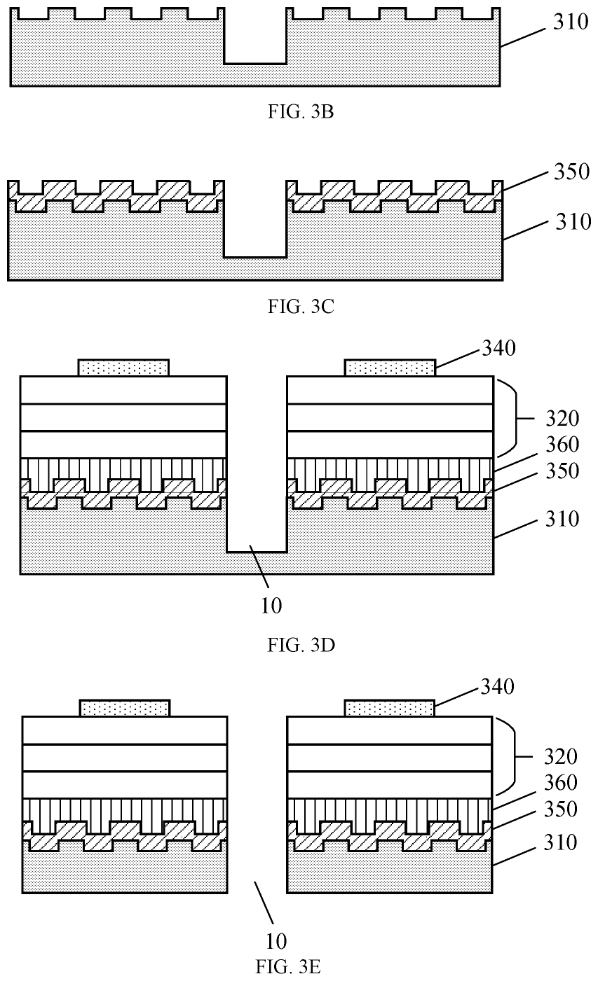

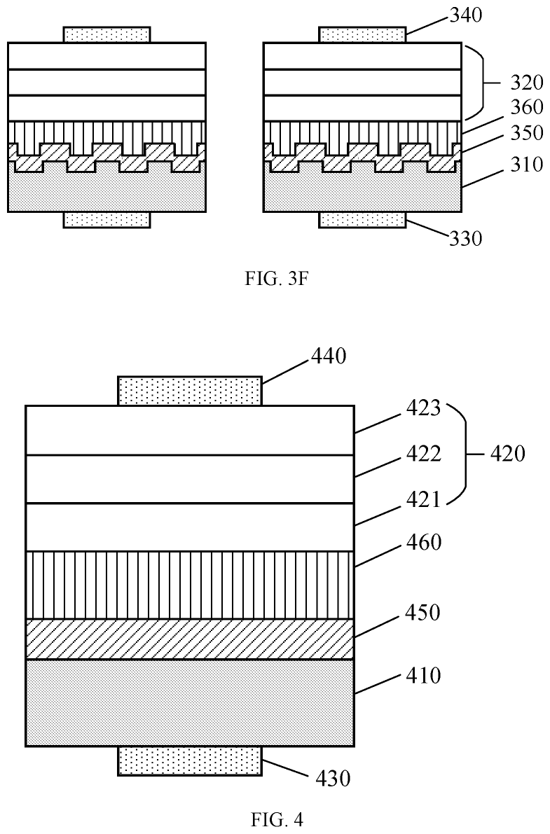

FIG. 2 is a schematic flowchart of a manufacturing method for a light emitting diode with a vertical structure according to another embodiment of the present application. FIG. 3A to 3F are schematic structural diagrams illustrating a manufacturing method for a light emitting diode with a vertical structure according to an exemplary of the present application. As shown in FIG. 2 and FIG. 3A to FIG. 3F, the manufacturing method includes the following contents.

S210: forming a metal atom layer on a substrate with at least one groove, the at least one groove used to separate the substrate into multiple pre-discrete structures.

Specifically, as shown in FIG. 3A, in an embodiment, the at least one groove 10 may be disposed on the substrate 310, which is used to separate the substrate 310 into the multiple pre-discrete structures. The metal atom layer is formed on the substrate with the at least one groove 10, i.e., the metal atom layer is separately formed on the multiple pre-discrete structures of the substrate.

Optionally, as shown in FIG. 3B and FIG. 3C, in an embodiment, before the metal atom layer 350 is formed, an upper surface of the substrate 310 is patterned first, and then a uniform metal atom layer 350 is formed on the upper surface of the substrate 310 with the patterned structure, so that the metal atom layer 350 may have the patterned structure corresponding to the patterned structure of the substrate 310.

S220: forming an n-type buffer layer on the metal atom layer.

S230: forming a light emitting structure on the n-type buffer layer.

S240: disposing a p electrode on the light emitting structure.

As shown in FIG. 3D, in an embodiment, the n-type buffer layer 360, the light emitting structure 320 and the p electrode 340 may be sequentially formed on the metal atom layer 350.

S250: performing a thinning processing on one side, away from the metal atom layer, of the substrate, so that a thickness of a thinned substrate is less than or equal to a depth of the at least one groove, separating the multiple pre-discrete structures into multiple light emitting units that are independent from each other.

As shown in FIG. 3E, the thinning processing is performed on the substrate 310 from a bottom of the substrate 310, so that the multiple light emitting units that are independent from each other can be obtained directly, the steps such as cutting are avoided, and a quality of a device is improved.

Specifically, when the thinning processing is performed on the substrate 310 with the at least one groove 10, if a thinning thickness is greater than or equal to a distance between a bottom of the groove 10 and a bottom of the substrate 310, i.e., the thickness of the thinned substrate 310 is less than or equal to the depth of the groove 10, the bottom of the groove 10 may be removed. In other words, a connection between the multiple pre-discrete structures separated by the at least one groove 10 may be removed. In this way, the multiple pre-discrete structures may be completely separated to form multiple discrete structures that are independent from each other (i.e., the multiple light emitting units).

Optionally, in an embodiment, the depth of the at least one groove is greater than half of a thickness of the substrate, so that in the subsequent thinning processing, it is easier to separate the multiple pre-discrete structures into the multiple discrete structures that are independent from each other.

Optionally, in another embodiment, when the at least one groove includes multiple grooves, depths of the multiple grooves are all equal, so that in the subsequent thinning processing, all the pre-discrete structures can be separated at the same time, simplifying a manufacturing process.

Further, in another embodiment, the at least one groove on the substrate may be filled with an insulating material, such as silicon dioxide or silicon nitride. The at least one groove is filled with the insulating material, so that better isolation effect can be achieved, making the subsequent process easier to implement, and making a quality of a final discrete device better.

S260: disposing an n electrode on the one side, away from the metal atom layer, of each of the multiple light emitting units.

As shown in FIG. 3F, after the multiple light emitting units that are independent from each other are obtained, the n electrode 330 may be disposed below each light emitting unit to obtain a complete discrete device.

Based on the manufacturing method for the light emitting diode with the vertical structure provided in the embodiments of the present application, the substrate with the at least one groove is adopted, and the vertical structure is manufactured on the multiple pre-discrete structures separated by the at least one groove, so that the multiple discrete devices can be obtained only by using the thinning processing, cutting steps are avoided, damage of the device is reduced, improving the quality of the light emitting diode with the vertical structure.

It should be understood that some of the steps in the method of the embodiments shown in FIG. 2 are the same as those shown in FIG. 1, and the details and effects are no longer described here.

FIG. 4 is a schematic structural diagram of a light emitting diode with a vertical structure according to an embodiment of the present application. As shown in FIG. 4, the light emitting diode with the vertical structure includes: a substrate 410, the substrate 410 being an n-type substrate; a metal atom layer 450 formed on the substrate 410; an n-type buffer layer 460 formed on the metal atom layer 450; a light emitting structure 420 formed on the n-type buffer layer 460, the light emitting structure 420 including an n-type semiconductor layer 421, an active layer 422 and a p-type semiconductor layer 423 from bottom to top; a p electrode 440 disposed on the light emitting structure 420; and an n electrode 430 disposed on one side, away from the metal atom layer, of the substrate.

Optionally, in an embodiment, the metal atom layer 450 is an Al atom layer.

FIG. 5 is a schematic structural diagram of a light emitting diode with a vertical structure according to another embodiment of the present application. The light emitting diode with the vertical structure includes: a substrate 510, the substrate 510 being an n-type substrate; a metal atom layer 550 formed on the substrate 510, the metal atom layer 550 having a continuous patterned structure; an n-type buffer layer 560 formed on the metal atom layer 550; a light emitting structure 520 formed on the n-type buffer layer 560, the light emitting structure 520 including an n-type semiconductor layer 521, an active layer 522 and a p-type semiconductor layer 523 from bottom to top; a p electrode 540 disposed on the light emitting structure 520; and an n electrode 530 disposed on one side, away from the metal atom layer, of the substrate.

FIG. 6 is a schematic structural diagram of a light emitting diode with a vertical structure according to another embodiment of the present application. The light emitting diode with the vertical structure includes: a substrate 610, the substrate 610 being an n-type substrate; a metal atom layer 650 formed on the substrate 610, the metal atom layer 650 having a discontinuous patterned structure; an n-type buffer layer 660 formed on the metal atom layer 650; a light emitting structure 620 formed on the n-type buffer layer 660, the light emitting structure 620 including an n-type semiconductor layer 621, an active layer 622 and a p-type semiconductor layer 623 from bottom to top; a p electrode 640 disposed on the light emitting structure 620; and an n electrode 630 disposed on one side, away from the metal atom layer, of the substrate.

FIG. 7 is a schematic structural diagram of a light emitting diode with a vertical structure according to another embodiment of the present application. The light emitting diode with the vertical structure includes: a substrate 710, the substrate 710 being an n-type substrate, and an upper surface of the substrate 710 having a patterned structure; a metal atom layer 750 formed on the substrate 710, the metal atom layer 750 having the patterned structure corresponding to the substrate 710; an n-type buffer layer 760 formed on the metal atom layer 750; a light emitting structure 720 formed on the n-type buffer layer 760, the light emitting structure 720 including an n-type semiconductor layer 721, an active layer 722 and a p-type semiconductor layer 723 from bottom to top; a p electrode 740 disposed on the light emitting structure 720; and an n electrode 730 disposed on one side, away from the metal atom layer, of the substrate.

The metal atom layer 750 has the patterned structure corresponding to the upper surface of the substrate 710, so that the metal atom layer can be more uniform, the patterned structure is more stable, and light extraction efficiency of the light emitting diode with the vertical structure is better improved.

FIG. 8 is a schematic structural diagram of a light emitting diode with a vertical structure according to another embodiment of the present application. The light emitting diode with the vertical structure includes: a substrate 810, the substrate 810 being an n-type substrate, and an upper surface of the substrate 810 having a patterned structure; a metal atom layer 850 formed between concave regions on the patterned structure of the substrate 810; an n-type buffer layer 860 formed on the metal atom layer 850; a light emitting structure 820 formed on the n-type buffer layer 860, the light emitting structure 820 including an n-type semiconductor layer 821, an active layer 822 and a p-type semiconductor layer 823 from bottom to top; a p electrode 840 disposed on the light emitting structure 820; and an n electrode 830 disposed on one side, away from the metal atom layer, of the substrate.

That is, in the embodiment shown in FIG. 8, the metal atom layer 850 is partially formed on the substrate 810. Specifically, the metal atom layer 850 is formed on a convex region between the concave regions on the patterned structure on the upper surface of the substrate 810, and is not disposed in the concave regions.

FIG. 9 is a schematic structural diagram of a light emitting diode with a vertical structure according to another embodiment of the present application. The light emitting diode with the vertical structure includes: a substrate 910, the substrate 910 being an n-type substrate, and an upper surface of the substrate 910 having a patterned structure; the metal atom layer 950 formed in concave regions on the patterned structure of the substrate 910; an n-type buffer layer 960 formed on the metal atom layer 950; a light emitting structure 920 formed on the n-type buffer layer 960, the light emitting structure 920 including an n-type semiconductor layer 921, an active layer 922 and a p-type semiconductor layer 923 from bottom to top; a p electrode 940 disposed on the light emitting structure 920; and an n electrode 930 disposed on one side, away from the metal atom layer, of the substrate.

That is, in the embodiment shown in FIG. 9, the metal atom layer 950 is partially formed on the substrate 910. Specifically, the metal atom layer 950 is formed in the concave regions on the patterned structure of the upper surface of the substrate 910, and is not disposed on a convex region between the concave regions.

Based on the light emitting diode with the vertical structure provided in the embodiments of the present application, the n-type substrate with the conductivity is adopted, and the metal atom layer and the n-type buffer layer are sequentially formed on the n-type substrate, so that the conductivity of the device can be ensured. As for such the device, there is no need to replace the substrate after a layer structure is formed, i.e., the substrate of the device is a substrate used to grow the epitaxial layer, so that the manufacturing cost is low, the manufacturing efficiency is high, and the quality of the device is better. In addition, since the metal atom layer is disposed on the substrate, and the metal atom layer may also have the patterned structure, so that the process flow of the light emitting diode with the vertical structure is simplified while effectively improving the light extraction efficiency of the light emitting diode with the vertical structure.

It should be understood that the structural embodiments shown in FIG. 4 to FIG. 9 correspond to the method embodiments shown in FIG. 1, and the details and effects are no longer described here.

In an embodiment of the present application, an LED display panel is also provided, including the light emitting diode with the vertical structure shown in any embodiment in FIG. 4 to FIG. 8 above.

It should be noted that in this specification, the terms “dispose”, “form”, and “manufacture”, etc. should be understood in a broad sense unless otherwise clearly defined and limited. Those of ordinary skill in the art, can understand the specific meaning of the above terms in this application.

It should also be noted that the orientation or positional relationship indicated by the terms “up”, “down”, “inside”, “outside”, etc. is based on the orientation or positional relationship shown in the drawings, or the orientation or positional relationship usually placed when the invented product is used. It is only to facilitate the description of the application and simplify the description, rather than to indicate or imply that the device or component referred to must have a specific orientation, be constructed and operated in a specific direction, and therefore, it cannot be understood as a restriction on this application.

The above are only preferred embodiments of the present application and are not intended to limit the present application. Any modification, equivalent replacement, etc. made within the spirit and principle of this application shall be included within the protection scope of this application.

What is claimed is:

1. A manufacturing method for a light emitting diode with a vertical structure, comprising:
forming a metal atom layer on a substrate, the substrate being an n-type substrate;
forming an n-type buffer layer on the metal atom layer;
forming a light emitting structure on the n-type buffer layer, the light emitting structure comprising an n-type semiconductor layer, an active layer and a p-type semiconductor layer from bottom to top;
disposing a p electrode on the light emitting structure; and
disposing an n electrode on one side, away from the metal atom layer, of the substrate.

2. The manufacturing method according to claim 1, wherein the metal atom layer is an Al atom layer.

3. The manufacturing method according to claim 1, wherein the forming a metal atom layer on a substrate comprises:
forming the metal atom layer with a patterned structure on the substrate, wherein the patterned structure comprises a continuous pattern and a discontinuous pattern.

4. The manufacturing method according to claim 3, wherein the forming the metal atom layer with a patterned structure on the substrate comprises:
patterning an upper surface of the substrate; and
forming the metal atom layer on the upper surface of the substrate with the patterned structure, so that the metal atom layer has the patterned structure.

5. The manufacturing method according to claim 1, wherein the forming a metal atom layer on a substrate comprises:
partially forming the metal atom layer on the substrate.

6. The manufacturing method according to claim 5, wherein the partially forming the metal atom layer on the substrate comprises:
patterning an upper surface of the substrate; and
forming the metal atom layer on a partial region of the upper surface of the substrate with a patterned structure.

7. The manufacturing method according to claim 1, wherein before disposing an n electrode on one side, away from the metal atom layer, of the substrate, the manufacturing method further comprises:
performing a thinning processing on the one side, away from the metal atom layer, of the substrate.

8. The manufacturing method according to claim 7, wherein the thinning processing comprises at least one of etching and polishing.

9. The manufacturing method according to claim 7, wherein at least one groove is disposed on the substrate for separating the substrate into multiple pre-discrete structures, and
a thickness of a thinned substrate is less than or equal to a depth of the at least one groove based on the thinning process, so as to separate the multiple pre-discrete structures into multiple light emitting units that are independent from each other.

10. The manufacturing method according to claim 9, wherein the at least one groove is filled with an insulating material.

11. The manufacturing method according to claim 9, wherein the disposing an n electrode on one side, away from the metal atom layer, of the substrate comprises:
disposing the n electrode on the one side, away from the metal atom layer, of each of the multiple light emitting units.

12. A light emitting diode with a vertical structure, comprising:
a substrate, the substrate being an n-type substrate;
a metal atom layer formed on the substrate;
an n-type buffer layer formed on the metal atom layer;
a light emitting structure formed on the n-type buffer layer, the light emitting structure comprising an n-type semiconductor layer, an active layer and a p-type semiconductor layer from bottom to top;
a p electrode disposed on the light emitting structure; and
an n electrode disposed on one side, away from the metal atom layer, of the substrate.

13. The light emitting diode with the vertical structure according to claim 12, wherein the metal atom layer is an Al atom layer.

14. The light emitting diode with the vertical structure according to claim 12, wherein the metal atom layer has a patterned structure, and the patterned structure comprises a continuous pattern and a discontinuous pattern.

15. The light emitting diode with the vertical structure according to claim 14, wherein an upper surface of the substrate has the patterned structure corresponding to the metal atom layer.

16. The light emitting diode with the vertical structure according to claim 12, wherein materials of the n-type semiconductor layer and the p-type semiconductor layer are group III-Nitrides.

17. The light emitting diode with the vertical structure according to claim 12, wherein a horizontal width of the light emitting diode with the vertical structure is less than 500 μm.

18. The light emitting diode with the vertical structure according to claim 12, wherein a horizontal width of the light emitting diode with the vertical structure is less than 100 μm.

19. A light emitting diode (LED) display panel, comprising a light emitting diode with a vertical structure,
wherein the light emitting diode with the vertical structure comprises:
a substrate, the substrate being an n-type substrate;
a metal atom layer formed on the substrate;
an n-type buffer layer formed on the metal atom layer;
a light emitting structure formed on the n-type buffer layer, the light emitting structure comprising an n-type semiconductor layer, an active layer and a p-type semiconductor layer from bottom to top;
a p electrode disposed on the light emitting structure; and
an n electrode disposed on one side, away from the metal atom layer, of the substrate.

20. The LED display panel according to claim 19, wherein the metal atom layer has a patterned structure, and the patterned structure comprises a continuous pattern and a discontinuous pattern.
